(19) United States
(12) Patent Application Publication
(10) Pub. No.: US 2015/0206819 A1
(43) Pub. Date: Jul. 23, 2015

(54) ELECTRONIC COMPONENT PACKAGE AND METHOD FOR MANUFACTURING THE SAME

(71) Applicant: Panasonic Intellectual Property Management Co., Ltd., Osaka (JP)

(72) Inventors: Takashi Ichiryu, Osaka (JP); Seiichi Nakatani, Osaka (JP); Yoshihisa Yamashita, Kyoto (JP)

(21) Appl. No.: 14/422,294

(22) PCT Filed: Dec. 20, 2013
(86) PCT No.: PCT/JP2013/007504

§ 371 Date: Feb. 18, 2015

(30) Foreign Application Priority Data
Dec. 21, 2012 (JP) 2012-279830

(51) Int. Cl. H01L 23/34; H01L 23/50; H01L 23/28; H01L 21/56; H01L 21/768

(52) U.S. Cl. CPC H01L 23/34; H01L 21/56; H01L 21/76877; H01L 23/28; H01L 23/50

(57) ABSTRACT

There is provided a method for manufacturing an electronic component package. The method comprises the steps: (i) forming a package precursor in which an electronic component is embedded in a sealing resin layer such that an electrode of the electronic component is exposed at a surface of the sealing resin layer; (ii) disposing a metal foil having a through-hole on the surface of the sealing resin layer such that the through-hole of the metal foil is positioned in an opposed relation to the electrode of the electronic component; and (iii) forming a metal plating layer on the metal foil, wherein the formation of the metal plating layer in the step (iii) is performed by a dry plating process and a subsequent wet plating process, whereby the through-hole is filled with the metal plating layer, and the metal foil and the metal plating layer are integrated with each other.

### TECHNICAL FIELD

The present disclosure relates to an electronic component package and a method for manufacturing the electronic component package. More particularly, the present disclosure relates to a package product equipped with an electronic component, and a method for manufacturing such package product.

### BACKGROUND OF THE INVENTION

With the advance of electronic devices, various package technologies have been developed in the electronics field. For example, a packaging (i.e., packaging technique) using a circuit substrate or a lead frame has been developed for a mounting of electronic components such as IC and inductor. That is, there have been “package with circuit substrate” and “package with lead frame” as a general package form for the electronic component.

“Package with circuit substrate” (see FIG. 5A) has such a form that the electronic component has been mounted on the circuit substrate. This package is generally classified as “Wire Bonding type (W/B t)” and “Flip Chip type (F/C type)”. While on the other hand, “package with lead frame” (see FIG. 5B) has such a form that a lead frame, which may be composed of a lead or die pad, is included therein. In this lead frame-type package as well as the package with circuit substrate, a bonding of the various electronic components is provided by a soldering or the like.

### PATENT DOCUMENTS (PRIOR ART PATENT DOCUMENTS)

### PATENT DOCUMENT 1: JP 2010-80528 A

### PATENT DOCUMENT 2: JP 10-223832 A

### PATENT DOCUMENT 3: JP 2011-134817 A

### DISCLOSURE OF THE INVENTION

### Problems to be Solved by the Invention

The related art techniques, however, disadvantageously do not have sufficient heat-releasing properties and connection reliability in high-density packaging.

An embodiment of the present invention has been created under the above circumstances, and an object of an embodiment of the present invention is to provide an electronic component package which can improve the heat-releasing properties and the connection reliability in the high-density packaging, and a method for manufacturing the electronic component package.

### Means for Solving the Problem

In order to achieve the above-mentioned object, an embodiment of the present invention provides a method for manufacturing an electronic component package, the method comprising the steps:

(i) forming a package precursor in which an electronic component is embedded in a sealing resin layer such that an electrode of the electronic component is exposed at a surface of the sealing resin layer;

(ii) disposing a metal foil having a through-hole on the surface of the sealing resin layer such that the through-hole of the metal foil is positioned in an opposed relation to the electrode of the electronic component; and

(iii) forming a metal plating layer on the metal foil,

wherein the formation of the metal plating layer in the step (iii) is performed by a dry plating process and a subsequent wet plating process, whereby the through-hole of the metal foil is filled with the metal plating layer, and the metal foil and the metal plating layer are integrated with each other.

Furthermore, an embodiment of the present invention also provides an electronic component package, comprising:

a sealing resin layer;

an electronic component embedded in the sealing resin layer; and

a metal wiring layer formed on the sealing resin layer and in contact with an electrode of the electronic component,

wherein the metal wiring layer is composed of a metal plating layer and a metal foil, the metal plating layer being in a direct contact with the electrode of the electronic component and the metal foil being integrated with the metal plating layer,

the metal plating layer has a two-layered structure of a dry plating layer and a wet plating layer, and the dry plating layer has a bended form to be in a direct contact with the electrode of the electronic component, and the wet plating layer fills a recessed portion of the dry plating layer such that the wet plating layer has a form of thickness on the metal foil, the recessed portion being due to the bended form.

### Effect of the Invention

The electronic component package according to an embodiment of the present invention can improve the heat-releasing properties and the connection reliability in high-density packaging.

### BRIEF DESCRIPTION OF THE DRAWINGS

FIGS. 1A to 1I are process-cross sectional views schematically illustrating a manufacturing method of an electronic component package according to an embodiment of the present invention.

FIG. 2 is a schematic cross-sectional view of the electronic component package according to an embodiment of the present invention.

FIG. 3 is a schematic cross-sectional view of the electronic component package according to another embodiment of the present invention.

FIG. 4 is a schematic cross-sectional view of the electronic component package according to another embodiment of the present invention.

FIGS. 5A and 5B are cross-sectional views schematically illustrating a configuration of an electronic component package in the related art.

### DETAILED DESCRIPTION OF THE INVENTION

### Findings as Basis for Invention

The inventors have found out that the conventional packaging technologies mentioned in the paragraph “BACKGROUND OF THE INVENTION” have the following problems.

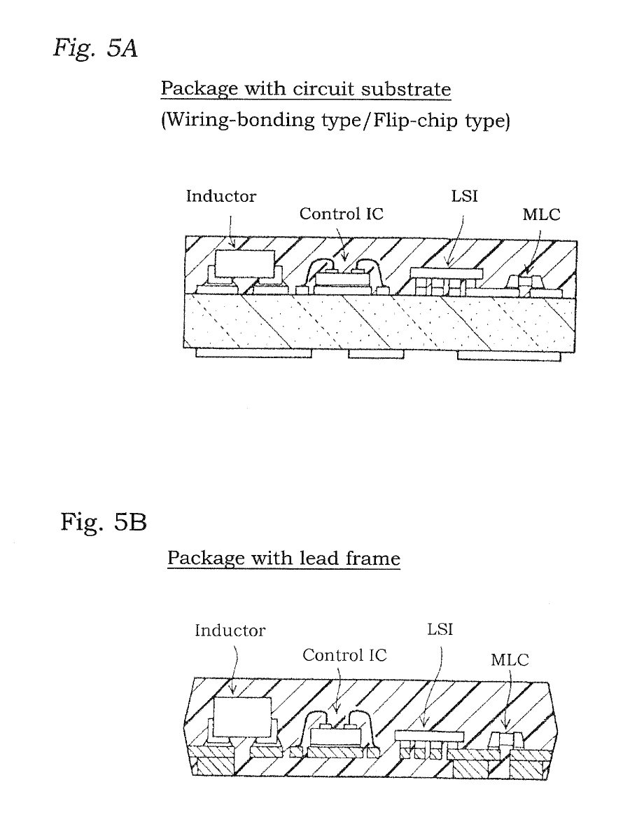

The “package with the circuit board” (see FIG. 5A) can provide the high-density packaging, but cannot have the sufficient heat dissipation because the circuit board is applied. Moreover, the substrate itself also costs a lot. Further, the cost of wire bonding or flip-chip mounting is not negligible. Thus, it is further desired to reduce the cost of the package. The “lead frame-type package” (see FIG. 5B) is not appropriate for the high-density packaging because the lead frame in itself makes it difficult to provide a fine process.

Since both packages are soldered, the entire package sealed with resin material might have the problem of the so-called “solder flash”. That is, due to the heating for soldering, solder material used for the connection of package components can be re-melted, and thus the re-melted solder material may cause a short circuit. Therefore, the connection reliability cannot be disadvantageously sufficient.

An embodiment of the present invention has been created under the above circumstances. That is, a main object of an embodiment of the present invention is to provide an electronic component package: (1) which has good heat-releasing properties; (2) which can reduce mounting cost; and (3) which has the sufficient connection reliability, and a method for manufacturing the electronic component package.

Thus, rather than addressing as merely extensions of conventional arts, the inventors of the present application tried to accomplish the above objects by addressing from a new point of view. As a result, the inventors have created the invention of an electronic component package and a manufacturing method thereof, both of which are capable of achieving the above objects.

Specifically, an embodiment of the present invention provides a method for manufacturing an electronic component package, the method comprising the steps:

(i) forming a package precursor in which an electronic component is embedded in a sealing resin layer such that an electrode of the electronic component is exposed at a surface of the sealing resin layer;

(ii) disposing a metal foil having a through-hole on the surface of the sealing resin layer such that the through-hole of the metal foil is positioned in an opposed relation to the electrode of the electronic component; and

(iii) forming a metal plating layer on the metal foil,

wherein the formation of the metal plating layer in the step (iii) is performed by a dry plating process and a subsequent wet plating process, whereby the through-hole of the metal foil is filled with the metal plating layer, and the metal foil and the metal plating layer are integrated with each other.

In an embodiment of the present invention, the metal wiring layer having a form of thickness is provided directly on the electrode exposed surface of the electronic component, which can effectively dissipate heat from the electronic component via the metal wiring layer. Specifically, the metal foil forming the metal wiring layer is in direct contact with the sealing resin layer, and the metal plating layer forming the metal wiring layer is in direct contact with the electrode of the electronic component, which enables the effective heat dissipation of heat from the electronic components via the metal foil and the electrodes of the electronic components. In the present invention, the soldering is not performed inside the package. Thus, the inconveniences such as the solder flash can be avoided to thereby improve the connection reliability. Moreover, in an embodiment of the present invention, the packaging can be achieved without using a substrate and with an easy process as compared to the wire bonding or flip-chip packaging, thus achieving lower cost of the packaging.

The electronic component package and the manufacturing method thereof according to an embodiment of the present invention will be described below.

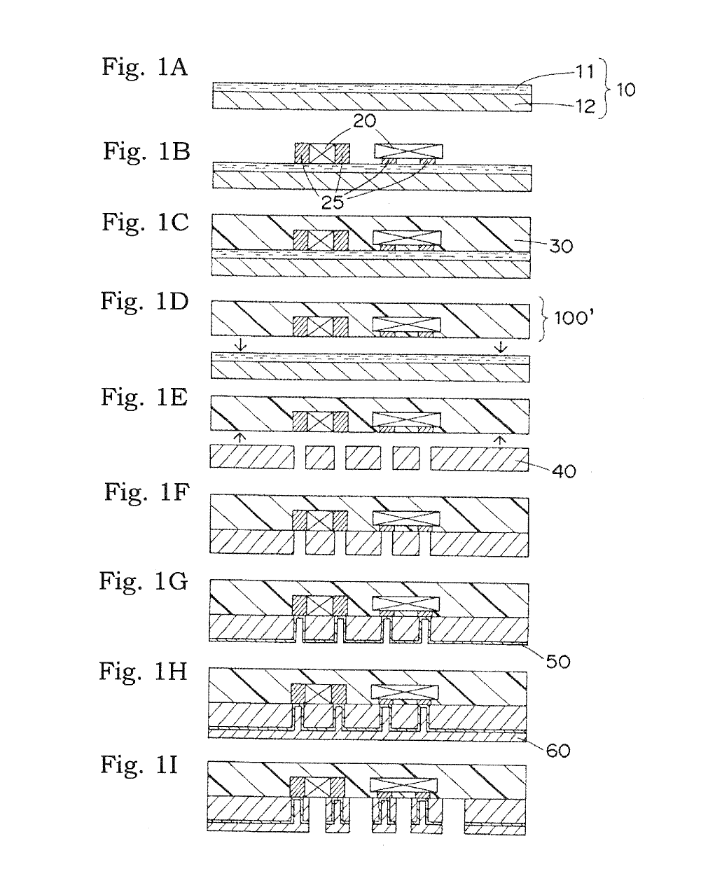

Firstly, as shown in FIG. 1A, an adhesive carrier 10 is provided. The adhesive carrier 10 may be, for example, a carrier sheet composed of a substrate and an adhesive layer. That is, as shown in FIG. 1A, the carrier sheet has a two-layered structure in which the adhesive layer 11 is provided on a supporting base 12. It is preferred that the supporting base 12 is flexible.

The supporting base 12 may be any suitable sheet-like part as long as it cannot adversely affect “disposing/placing of electronic component 20” or “formation of sealing resin layer 30”. For example, the material for the supporting base 12 may be a resin, a metal, and/or a ceramic. Examples of the resin for the supporting base 12 may include a polyester resin (e.g., polyethylene terephthalate, polyethylene naphthalate), an acrylic resin (e.g., polymethyl methacrylate), a polycycloolefin resin and a polycarbonate. Examples of metal for the supporting base 12 can include iron, copper, aluminum, and an alloy thereof.

Examples of ceramic for the supporting base 12 can include apatite, alumina, silica, silicon carbide, silicon nitride and boron carbide. The thickness of the supporting base 12 itself is in a range of, preferably 0.1 mm to 2.0 mm, and more preferably 0.2 mm to 1.0 mm (for example, 0.2 mm), because of its “sheet-like” form.

While on the other hand, the adhesive layer 11 may be any suitable one as long as it has an adhesive property with respect to the electronic component 20. For example, the adhesive layer 11 itself may comprise at least one kind of adhesive material selected from the group consisting of acrylic resin-based adhesive, urethane resin-based adhesive, silicone resin-based adhesive and epoxy resin adhesive. The thickness of the adhesive layer 11 is preferably in the range of 2 μm to 50 μm, more preferably in the range of 5 μm to 20 μm (for example, 10 μm). As the adhesive layer 11, a double-faced adhesive tape may be used. In this regard, the double faced adhesive tape wherein an adhesive layer is provided on both principal surfaces of a resin film layer (e.g., PET film) may be used, for example.

Next, as shown in FIG. 1B, at least one type of electronic component 20 is disposed on the adhesive carrier 10. That is, the electronic component 20 is attached to the adhesive carrier 10. The electronic component 20 may be any suitable one as long as it is a circuit component/element used in the electronics packaging field. Examples of the electronic component may include an IC (e.g., control IC), an inductor, a semiconductor element (e.g., MOS: metal-oxide semiconductor), a capacitor, a power element, a light-emitting element (e.g., LED), a chip resistor, a chip capacitor, a chip varistor, a chip thermistor and a chip laminate filter, a connection terminal and the like.

The electronic components 20 is preferably arranged such that the electrodes 25 of the electronic component 20 contact with the adhesive carrier 10. Thus, the electrodes 25 of the electronic components 20 can be appropriately exposed by a peeling operation mentioned below.

Then, as shown in FIG. 1C, a sealing resin layer 30 is formed on the adhesive carrier 10 such that the electronic component 20 are covered with the sealing resin layer 30. The formation of the sealing resin layer 30 can be performed by applying a resin material onto an adhesive surface of the adhesive carrier 10 by a spin-coating process or a doctor-blade process, followed by being subjected to a heat treatment or a light-exposure treatment. (In other words, the sealing resin layer 30 can be provided by subjecting the applied resin material to a heat or light curing treatment.) Alternatively, the sealing resin layer 30 may be provided by putting a resin film on the adhesive surface of the adhesive carrier 10. Furthermore, the sealing resin layer 30 may be provided by filling an uncured powdered or liquid resin into a die, followed by a heat curing thereof. The material for the sealing resin layer 30 may be any suitable one as long as it exhibits electrical insulation properties. For example, the material of the sealing resin layer may be an epoxy-based resin or a silicone-based resin. The thickness of the sealing resin layer 30 is preferably in the approximate range of 0.5 mm to 5.0 mm, and more preferably in the approximate range of 1.2 mm to 1.8 mm.

Then, as shown in FIG. 1D, the adhesive carrier 10 is peeled off to thereby expose the electrode 25 of the electronic component 20 at the surface of the sealing resin layer 30, thereby forming a precursor 100′ of an electronic component package.

Next, as shown in FIGS. 1E and 1F, a metal foil 40 having through-holes is provided such that the metal foil 40 is in contact with an exposed surface of the sealing resin layer 30 and an exposed surface of the electrodes 25 of the electronic components 20. At this time, the metal foil 40 is aligned such that the through-holes are positioned in an opposed relation to the electrodes 25 of the electronic components 20. Thus, the electrodes 25 of the electronic components 20 are exposed from the through-holes provided in the metal foil 40. The thickness of the metal foil 40 is preferably in a range of 9 μm to 2000 μm, and more preferably in a range of 18 μm to 1000 μm. The metal foil 40 preferably comprises at least one kind of metal material selected from the group consisting of Cu (copper), Ni (nickel), and Al (aluminum). A formation method for the through-hole is not particularly limited as long as it is used in the field of electronics packaging. For example, a photolithography process can be available for the patterning, in which case a formation of resist layer, an exposure to the light and subsequent development, and an etching are sequentially performed. At this time, the adhesive carrier 10 is peeled away from the sealing resin layer 30 in the B-stage state, and the sealing resin layer 30 is aligned with the metal foil 40, and then heated and pressurized, so that the sealing resin layer 30 and the metal foil 40 are integrated with each other. Then, the resin layer is finally cured, which can improve the adhesion between the sealing resin layer 30 and the metal foil 40.

Then, as shown in FIG. 1G, a dry plating layer 50 is formed on the aligned metal foil 40 by the dry plating process. The parts of the dry plating layer 50 positioned inside the through-holes which are provided in the metal foil 40 are in direct contact with the electrodes 25 of the electronic components 20, and are formed to have a bended form along an outline of the through-hole.

Then, as shown in FIG. 1H, a wet plating layer 60 is formed on the aligned metal foil 40 by a wet plating process. The parts of the wet plating layer 60 positioned inside the through-holes provided in the metal foil 40 are formed to fill or embed recessed portions of the dry plating layer 50. Preferably, the dry plating layer 50 with its thickness of 100 nm to 1000 nm is formed by the dry plating process, and then the wet plating layer 60 with its thickness of 1 μm to 10 μm (corresponding to a thickness of the layer area other than the recessed portion of the dry plating layer 50) is formed on the dry plating layer 50 by the wet plating process. That is, the dry plating layer 50 is very thin, while the wet plating layer 60 is thicker than the dry plating layer 50.

The dry plating layer 50 formed by the dry plating process preferably comprises at least one kind of metal material selected from the group consisting of, for example, Ti (titanium), Cr (chrome), and Ni (nickel). The wet plating layer 60 formed by the wet plating process preferably comprises at least one kind of metal material selected from the group consisting of, for example, Cu (copper), Ni (nickel), and Al (aluminum). The dry plating layer 50 is formed as a single layer by way of example, but is not limited thereto. Alternatively, the dry plating layer 50 may be formed as a plurality of layers. For example, the dry plating layer 50 of a Ti thin film layer and a Cu thin film layer may be formed by sputtering (more specifically, the Cu thin layer may be formed after forming the Ti thin film layer). In this case, a thick Cu plating layer is preferably formed as the wet plating layer 60 on the sputtering layer of the obtained two-layered structure by electrolytic plating.

Thus, the metal plating layer composed of the dry plating layer 50 and wet plating layer 60 and having a form of thickness is formed on the metal foil 40. Thus, the metal plating layer and the metal foil 40 are integrated with each other, so that the electrodes 25 of the electronic components 20 are electrically connected to the metal foil 40. The metal foil 40 is provided on the exposed surface of the sealing resin layer 30 and the exposed surface of the electrodes 25 of the electronic components 20, whereby the metal foil 40 can be used as a heat-releasing part appropriate for releasing a heat from the electronic components 20. Since the dry plating layer 50, that is, the metal plating layer is in direct contact with the electrodes 25 of the electronic components 20, the metal foil 40 and the metal plating layer can be used as the heat-releasing part appropriate for releasing heat from the electronic components 20.

A manufacturing method according to an embodiment of the present invention performs the dry plating process, and thus can form the plating layer with a good adhesion by the subsequent wet plating process. Examples of the dry plating process include a vacuum plating process (Physical Vapor Deposition, i.e., PVD process) and a chemical vapor plating process (Chemical Vapor Deposition, i.e., CVD process). Examples of the vacuum plating process include a sputtering process, a vacuum deposition process, and an ion plating process. On the other hand, examples of the wet plating process include an electroplating process (e.g., electrolytic plating process), a chemical plating process, and a hot-dip plating process. In a preferred embodiment, the sputtering may be performed as the dry plating process, whereas the electroplating (e.g., electrolytic plating) may be performed as the wet plating process.

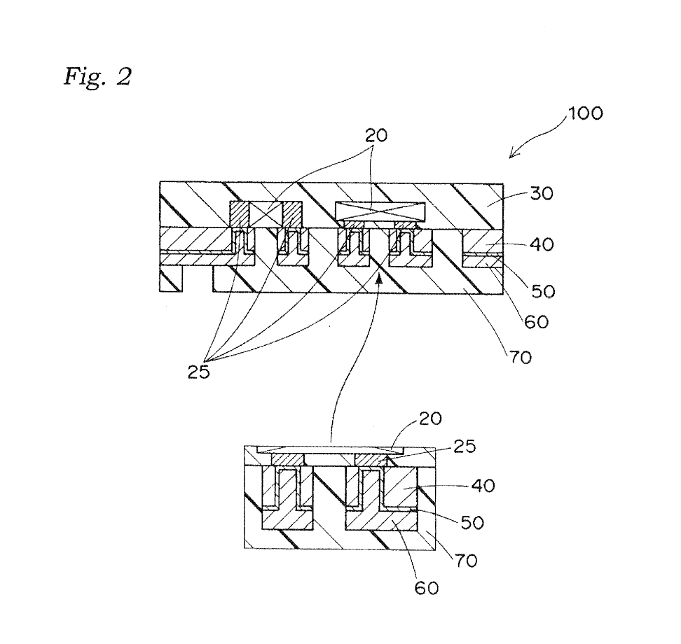

Then, as shown in FIG. 1I, the metal foil 40 and the metal plating layer is subjected to a patterning treatment to form a desired metal wiring layer. The patterning in itself is not particularly limited as long as it is used in the electronics packaging field. For example, a photolithography process can be available for the patterning, in which case a formation of resist layer, an exposure to the light and subsequent development, and an etching are sequentially performed. Subsequent to the patterning the metal foil 40 and the metal plating layer, a resist layer is preferably formed on the metal wiring layer. For example, a solder resist layer is preferably formed on the metal wiring layer. The formation of the resist layer 70 may be performed in the same way as the formation of the solder resist generally used in the field of electronics packaging. Finally, through a dicing process, the electronic component package 100 shown in FIG. 2 according to an embodiment of the present invention can be obtained.

As shown in FIG. 2, the electronic component package in an embodiment of the present invention comprises the sealing resin layer 30, the electronic components 20 embedded in the sealing resin layer 30, and the metal wiring layer (i) formed on the sealing resin layer 30 and (ii) which is in contact with the electrodes 25 of the electronic components 20. The metal wiring layer is composed of the metal plating layer in a direct contact with the electrodes 25 of the electronic components 20, and the metal foil 40 integrated with the metal plating layer. The metal foil 40 is in a direct contact with a part of the electrodes 25 of the electronic components 20 and the sealing resin layer 30. The metal foil 40 may be in contact with only the sealing resin layer. Alternatively, the metal plating layer is in direct contact with the electrodes 25 of the electronic components 20. The metal plating layer has a two-layered structure of the dry plating layer 50, and the wet plating layer 60, and extends locally through the internal region of the metal foil 40 having a thickness of 18 μm to 1000 μm. The dry plating layer 50 positioned in an opposed relation to the electrode 25 of the electronic component 20 has a bended form to be in a direct contact with the electrode 25 of the electronic component 20. Due to the bended form, a recessed portion is formed in the dry plating layer 50 positioned in the opposed relation to the electrode 25 of each electronic component 20. The wet plating layer 60 positioned in an opposed relation to the electrode 25 of each electronic component 20 is formed to fill the recessed portion of the dry plating layer 50 without any empty space. Thus, the part of the metal plating layer in direct contact with the electrode 25 of the electronic component 20 has a convex shape. The dry plating layer 50 has a thickness of 100 nm to 1000 nm. The wet plating layer 60 in the layer area other than the recessed portions of the dry plating layer 50 has a thickness of 1 μm to 10 μm. That is, the wet plating layer has a form of thickness on the metal foil 40. The thickness of the metal plating layer in the layer area other than the recessed portions of the dry plating layer 50 is thinner than that the thickness of the metal foil 40.

Thus, the electronic component package 100 according to an embodiment of the present invention has the following features. That is, the thick metal foil 40 is directly provided on the exposure surface of the sealing resin layer 30 and the exposure surface of the electrode 25 of the electronic component 20. Alternatively, the metal plating layer is directly formed on each electrode 25 of the electronic component 20. Thus, the electronic component package 100 in an embodiment of the present invention can have high heat-releasing properties. This package can effectively improve the characteristics and operating life of the electronic component, and can also effectively prevent the electronic components and sealing resin from changing properties and colors thereof due to heat. Further, the package has an excellent electric resistance as compared to the case of electric connection via wires or bumps. Thus, the package of an embodiment of the present invention effectively allows the larger current to flow therethrough. For example, when taking a light-emitting element package, such as a LED package, as one example, the present invention can achieve the light-emitting element package with the higher luminance due to the high heat-releasing properties, the large current, and the like.

The invention may take the following embodiment.

In this embodiment, firstly, the adhesive carrier 10 may be provided with the metal pattern layer disposed on the adhesive carrier 10. That is, the metal pattern layer may be provided to be attached to the adhesive carrier 10. The metal pattern layer provided to the adhesive carrier 10 is a metal layer subjected to the patterning treatment. Metal material for the metal pattern layer may comprise at least one kind of metal material selected from the group consisting of copper (Cu), aluminum (Al), silver (Ag), palladium (Pd), platinum (Pt), and nickel (Ni). The thickness of the metal pattern layer 80 is in a range of, preferably 5 μm to 100 μm, and more preferably 10 μm to 50 μm (for example, 18 μm). The patterning treatment of the metal pattern layer may be performed before the metal pattern layer is disposed on the adhesive carrier 10, or after the metal pattern layer is disposed on the adhesive carrier 10. The patterning treatment itself of the metal pattern layer is not particularly limited as long as the process is used in the field of electronics packaging. For example, a photolithography process can be available for the patterning, in which case a formation of resist layer, an exposure to the light and subsequent development, and an etching are sequentially performed.

Then, at least one kind of electronic component 20 may be placed in a carrier region not overlapped with respect to the metal pattern layer. That is, the electronic component 20 may be attached to the adhesive carrier 10 such that the placed electronic component 20 and the metal pattern layer are not overlapped with respect to each other on the adhesive carrier 10.

As for the placement of the electronic components 20, the metal pattern layer may be used as an cognition pattern. That is, at least a part of the metal pattern layer may be used as an alignment mark. For example, the alignment mark of the metal pattern layer can be used for positioning the electronic components 20 upon placing the electronic components 20. This makes it possible to precisely position the electronic component 20, which leads to an achievement of high reliability of the package. The alignment mark in itself may be included in a pattern of the metal pattern layer to serve for the exclusive purpose of the positioning of the electronic component. Alternatively, the pattern of the metal pattern layer, which serves for another purpose, may be used as the alignment mark. The alignment mark of the metal pattern layer is not limited to the use for positioning of the electronic component. The alignment mark can also be used for the positioning of other components/parts. Then, the sealing resin layer 30 may be formed on the adhesive carrier 10 such that the electronic component 20 and the metal pattern layer are covered with the sealing resin layer 30.

Next, the adhesive carrier 10 may be peeled off, and thereby the electrodes 25 of the electronic components 20 and the metal pattern layer are exposed at the surface of the sealing resin layer 30. An embodiment of the present invention makes it possible to provide a suitable detachability of the adhesive carrier 10 by the presence of the metal pattern layer. Specifically, the presence of the metal pattern layer improves an overall detachability of the adhesive carrier 10 with respect to the sealing resin layer 30, the metal pattern layer 10 being positioned locally at the interface between the sealing resin layer 30 and the adhesive carrier 10. This is due to the fact that a contact surface between the metal pattern layer and the adhesive carrier 10 exhibits a more reduced bonding property therebetween than that of a contact surface between the sealing resin layer 30 and the adhesive carrier 10. In other words, the local presence of the contact surface capable of exhibiting the reduced bonding property at the interface between the metal pattern layer and the adhesive carrier 10 improves the detachability of the adhesive carrier 10 with respect to the sealing resin layer 30 as a whole. This means that the metal pattern layer, which is positioned locally at the interface between the sealing resin layer 30 and the adhesive carrier 10, serves as “peel-promoting part” or “peel-facilitating part” (i.e., part for promoting the peeling of the adhesive carrier). In the present invention, the effective improved detachability between the adhesive carrier 10 and the sealing resin layer 30, which is due to the presence of the metal pattern layer, enables the peeling operation of the adhesive carrier 20 to be suitably performed.

It is preferred that the metal pattern layer having a gloss surface is used in order to more suitably perform the peeling of the adhesive carrier. Specifically, it is preferred that the gloss surface of the metal pattern layer is in a contact with the adhesive carrier 10 at a point in time before the peeling of the adhesive carrier 10. The metal pattern layer is preferably disposed on the adhesive carrier 10 such that the gloss surface of the metal pattern layer makes contact with the adhesive carrier 10 (especially the adhesive layer 11). The gloss surface of the metal pattern layer is capable of further reducing the bonding property of the contact surface between the metal pattern layer and the adhesive carrier 10, which leads to the more improved detachability of the adhesive carrier 10 with respect to the sealing resin layer 30.

In addition to or instead of “gloss surface”, the metal pattern layer preferably has a roughened surface. In this regard, it is preferred that the metal pattern layer is covered with the sealing resin layer 30 such that the roughened surface of the metal pattern layer is in contact with the sealing resin layer 30. This makes it possible to achieve a more suitable detachability of the adhesive carrier 10. It is preferred that the metal pattern layer is disposed on the adhesive carrier 10 such that the roughened surface of the metal pattern layer is an exposed surface. The sealing resin layer 30 is provided with respect to the exposed roughened surface, and thereby the metal pattern layer is covered with the sealing resin layer 30 such that the roughened surface and the sealing resin layer 30 are in contact with each other. The presence of “roughened surface” of the metal pattern layer can increase a bonding property between the metal pattern layer and the sealing resin layer 30, due to the fact that the roughened surface is in a dig state into the sealing resin layer 30. As such, the roughened surface of the metal pattern layer makes it possible to achieve a more suitable detachability of the adhesive carrier 10.

In a particularly preferred embodiment, the metal pattern layer has both of “gloss surface” and “roughened surface”. In the case where the metal pattern layer has the gloss surface and the roughened surface, it is preferred that the metal pattern layer is covered with the sealing resin layer 30 such that the gloss surface of the metal pattern layer is in contact with the adhesive carrier 10, and the roughened surface of the metal pattern layer and the sealing resin layer 30 are in bonding state with each other. This makes it possible to achieve both of “improved adhesion between the metal pattern layer and the sealing resin layer 30” and “improved detachability between the sealing resin layer 30 and the adhesive carrier 10”.

The term “roughened surface” as used herein means that a principal surface of the metal pattern layer has a rough surface (i.e., fine concave-convex surface). For example, the term “roughened surface” substantially means that an arithmetic mean roughness Rz of the surface of the metal pattern layer is 5.0 μm or higher, preferably 7.0 μm or higher. The upper limit for the arithmetic mean roughness Rz is not particularly limited, but may be about 10.0 μm or lower. While on the other hand, the term “gloss surface” as used herein means that a principal surface of the metal pattern layer has a smooth surface. For example, the “gloss surface” substantially means that an arithmetic mean roughness Ra of the surface of the metal pattern layer is 0.3 μm or lower, preferably 0.2 μm or lower (as for Rz, Rz is 2.0 μm or lower, preferably 1.0 μm or lower). In other words, the gloss surface of the metal pattern layer has the arithmetic mean roughness Ra of 0 (excluding 0) to 0.3 μm, preferably 0 (excluding 0) to 0.2 μm. The term “arithmetic mean roughness Ra” as used herein substantially means a mean value calculated from the sum of absolute values of the deviations from the average line over the length L of an evaluation section that is set in the roughness curve. While on the other hand, the term “arithmetic mean roughness Rz” for the surface of the metal pattern layer substantially is roughness “Rz” defined in JIS B0601. More specifically, the term “arithmetic mean roughness Rz” as used herein means the sum value (μm) of the average of absolute values from the uppermost mountain peak (Yp) to the fifth mountain peak (Yp) and the average of absolute values from the lowermost valley portion (Yv) to the fifth valley portion (Yv), the mountain peak and the valley portion being measured perpendicularly from the average line over the length of an evaluation section that is set in the roughness curve. See JIS B0601:1994.

Then, the metal foil 40 having through-holes is provided to be in contact with an exposed surface of the sealing resin layer 30 and an exposed surface of the electrode 25 of the electronic component 20. At this time, the metal foil 40 is aligned such that the through-holes are positioned in an opposed relation to the electrodes 25 of the electronic components 20. Thus, the electrodes 25 of the electronic components 20 are exposed from the through-holes provided in the metal foil 40. The through-holes can be provided not only in positions which is in an opposed relation to the electrodes 25 of the electronic components 20, but also in positions beneath the metal pattern layer. This arrangement can improve the heat-releasing properties from other parts other than the surface of the sealing resin layer 30 and the exposed surface of the electrode 25 of the electronic component 20. Then, the dry plating layer 50 is formed on the aligned metal foil 40 by the dry plating process. The parts of the dry plating layer 50 positioned inside the through-holes which are provided in the metal foil 40 are formed to have a bended form along an outline of the through-hole. Then, the wet plating layer 60 is formed on the aligned metal foil 40 by the wet plating process. The parts of the wet plating layer 60 positioned inside the through-holes provided in the metal foil 40 are formed to fill or embed recessed portions of the dry plating layer 50. Thus, the metal plating layer composed of the dry plating layer 50 and wet plating layer 60 and having a form of thickness is formed on the metal foil 40. Thus, the metal plating layer and the metal foil 40 are integrated with each other, so that the electrodes 25 of the electronic components 20 are electrically connected to the metal foil 40.

The present invention may take the following embodiments.

Firstly, the adhesive carrier 10 is provided. Next, at least one type of electronic component 20 is disposed on the adhesive carrier 10. That is, the electronic component 20 is attached to the adhesive carrier 10. Then, the sealing resin layer 30 is formed on the adhesive carrier 10 such that the electronic components 20 are covered with the sealing resin layer 30. Thereafter, the adhesive carrier 10 is peeled away to expose the electrode 25 of the electronic component 20 from the surface of the sealing resin layer 30, thereby producing the precursor 100′ of the electronic component package. Then, the adhesive layer 90 is formed on the surface of the metal foil 40 positioned in an opposed relation to the exposure surface of the sealing resin layer 30 and the exposure surfaces of the electrodes 25 of the electronic components 20, whereby a metal foil 40′ having the through-holes with the adhesive layer 90 is provided, the through-holes being positioned in an opposed relation to the electrodes 25 of the electronic components 20.

The adhesive layer 90 may comprise at least one or more adhesive materials selected from the group consisting of an acrylic resin-based adhesive, a urethane resin-based adhesive, a silicone resin-based adhesive, and epoxy resin-based adhesive. The thickness of the adhesive layer 90 is in a range of, preferably 2 μm to 50 μm, and more preferably 5 μm to 10 μm (for example, 10 μm).

A formation method of the through-hole in the metal foil 40′ with the adhesive layer is not particularly limited as long as it is used in the field of electronics fields. For example, a photolithography process can be available for the patterning, in which case a formation of resist layer, an exposure to the light and subsequent development, and an etching are sequentially performed. Further, the through-holes may be formed by machining process, such as laser processing, or punching process (punch process)

Then, the electronic components 20 are aligned such that the electrodes 25 of the electronic components 20 are positioned in an opposed relation to the respective through-holes, and the exposure surface of the sealing resin layer 30, the exposure surface of the electrode 25 of the electronic component 20, and the metal foil 40 are laminated via the adhesive layer 90. When the thermosetting resin or thermoplastic resin is used for the adhesive layer 90, a heating and/or pressurizing process is added according to material used, so that these layers can be laminated. Thus, the electronic component package with high reliability can be obtained without peeling the precursor 100′ of the electronic component package from the metal foil 40. Then, the dry plating layer 50 is formed on the aligned metal foil 40′ with the adhesive layer by the dry plating process. The parts of the dry plating layer 50 positioned inside the through-holes which are provided in the metal foil 40′ with the adhesive layer are formed to have a bended form along an outline of the through-hole. Then, the wet plating layer 60 is formed on the aligned metal foil 40′ with the adhesive layer by wet plating process. The parts of the wet plating layer 60 positioned inside the through-holes which are provided in the metal foil 40′ with the adhesive layer are formed to fill or embed recessed portions of the dry plating layer 50.

Thus, the metal plating layer composed of the dry plating layer 50 and wet plating layer 60 and having a form of thickness is formed on the metal foil 40′ with the adhesive layer. Thus, the metal plating layer and the metal foil 40′ with the adhesive layer are integrated with each other, so that the electrodes 25 of the electronic components 20 are electrically connected to the metal foil 40′ with the adhesive layer.

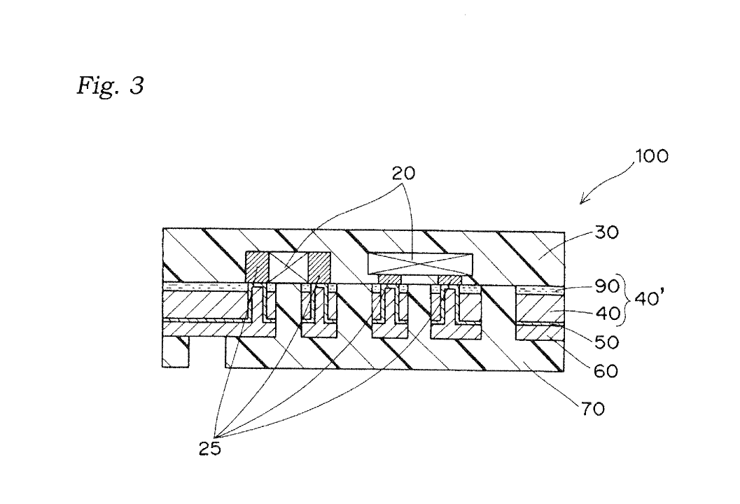

Finally, the metal foil 40′ with the adhesive layer is subjected to the patterning treatment to form a desired wiring (for example, a desired wiring pattern with an extraction electrode), and further the substrate is subjected to a dicing operation, so that as a result, the electronic component package 100 according to an embodiment of the present invention shown in FIG. 3 can be obtained.

As shown in FIG. 3, the electronic component package in an embodiment of the present invention comprises the sealing resin layer 30, the electronic components 20 embedded in the sealing resin layer 30, and the metal wiring layer formed on the sealing resin layer 30 and bonded to the electrodes 25 of the electronic components 20. The metal wiring layer is composed of the metal plating layer which is in a direct contact with the electrodes 25 of the electronic components 20, and the metal foil 40′ with the adhesive layer which is integrated with the metal plating layer. The metal plating layer has a two-layered structure of the dry plating layer 50, and the wet plating layer 60, and extends to locally through the internal region of the metal foil 40′ with the adhesive layer. The dry plating layer 50 has a bended form to be in a direct contact with the electrodes 25 of the electronic components 20. The wet plating layer 60 fills the recessed portion of the dry plating layer 50 formed due to the bended form such that the wet plating layer 60 has a form of thickness on the metal foil 40′ with the adhesive layer. The thickness of the metal plating layer in the layer area other than the recessed portions of the dry plating layer 50 is thinner than that of the metal foil 40′ with the adhesive layer.

The electronic component package 100 according to an embodiment of the present invention includes the thick metal foil 40′ with the adhesive layer directly disposed on the exposure surface of the sealing resin layer 30 and the exposure surfaces of the electrodes 25 of the electronic components 20, and thus can prevent the peeling of the metal foil 40′ with the adhesive layer from the exposure surface of the sealing resin layer 30 and the exposure surfaces of the electrodes 25 of the electronic components 20. Thus, the electronic component package with the high reliability which has the excellent heat-releasing properties can be obtained. This package can effectively improve the characteristics and operating life of the electronic component, and can also prevent the electronic components and sealing resin from changing properties and colors thereof due to heat. Further, the package has an excellent electric resistance as compared to the case of electric connection via wires or bumps. Thus, the package according to an embodiment of the present invention effectively allows the larger current to flow therethrough. For example, when taking a light-emitting element package, such as a LED package, as one example, the present invention can achieve the light-emitting element package with the higher luminance due to the high heat-releasing properties, the large current, and the like.

The present invention may take the following embodiment.

Firstly, the adhesive carrier 10 is provided. Next, at least one type of electronic component 20 is disposed on the adhesive carrier 10. That is, the electronic component 20 is attached to the adhesive carrier 10. Then, the sealing resin layer 30 is formed on the adhesive carrier 10 such that the electronic components 20 are covered with the sealing resin layer 30. Next, the adhesive carrier 10 is peeled away to thereby expose the electrodes 25 of the electronic components 20 from the surface of the sealing resin layer 30, thereby forming the precursor 100′ of the electronic component package. Then, the metal foil 40 with the through-holes having a tapered shape is provided to be in direct contact with the exposed surface of the sealing resin layer 30 and the exposed surfaces of the electrodes 25 of the electronic components 20. At this time, the metal foil 40 is aligned such that the through-holes having the tapered shape are positioned in an opposed relation to the electrodes 25 of the electronic components 20. Thus, the electrodes 25 of the electronic components 20 are exposed from the through-holes provided in the metal foil 40. The metal foil 40 is directly provided on the exposed surface of the sealing resin layer 30 and the exposed surfaces of the electrodes 25 of the electronic components 20, whereby the metal foil 40 can be used as a heat-releasing part appropriate for releasing the heat from the electronic components. Through-holes having the tapered shape may be further provided in the metal foil 40 positioned in an opposed relation to the exposure surface of the sealing resin layer 30. Thus, the electronic component package finally manufactured in this embodiment of the present invention has the tapered metal plating layers which extend to be in a direct contact with not only the electrodes 25 of the electronic component 20, but also the sealing resin layer 30.

At this time, an opening size of the through-hole positioned in the opposed relation to the exposure surface of the sealing resin layer 30 differs from that of the through-hole positioned in the opposed relation to the electrode 25 of the electronic component 20. Thus, the height of the metal plating layer in direct contact with the electrode 25 of the electronic component 20 differs from that of the metal plating layer in direct contact with the sealing resin layer 30. The opening size of the through-hole positioned in the opposed relation to the electrode 25 of the electronic component 20 is smaller than that of the through-hole positioned in the opposed relation to the exposure surface of the sealing resin layer 30. With this arrangement, the plating layer is easily formed at the wall surface of the through-hole positioned in the opposed relation to the electrode 25, which can reduce a defective connection.

On the other hand, the opening size of the through-hole positioned in the opposed relation to the exposure surface of the sealing resin layer 30 is larger than that of the through-hole positioned in the opposed relation to the electrode 25 of the electronic component 20. In particular, when the wiring layer is formed by patterning the metal foil 40, a position of the metal foil where the through-hole is positioned in the opposed relation to the exposure surface of the sealing resin layer 30 can serve as a land for soldering the electronic component package 100 to the substrate. Thus, a defective mounting which occur in mounting a solder ball, or a solder flash which occur in reflowing a solder ball can be suppressed.

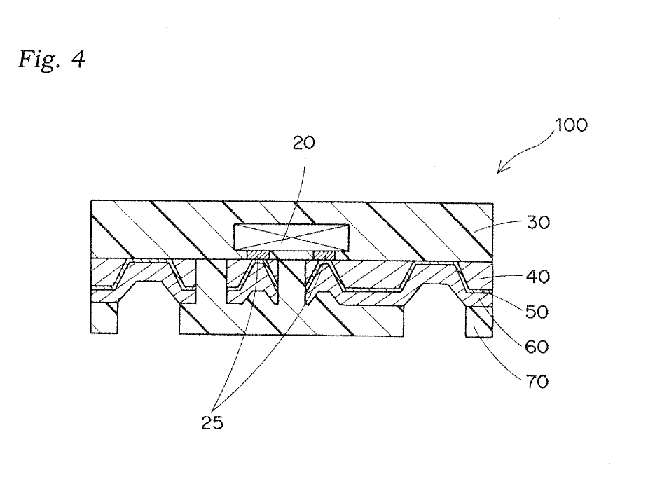

Finally, the metal foil 40 is subjected to the patterning treatment. The patterning treatment leads to a desired wiring formation, e.g., a desired pattern formation of wirings including an extraction electrode and further a dicing operation is performed, so that the electronic component package 100 of the present invention shown in FIG. 4 can be obtained.

As shown in FIG. 4, the electronic component package in an embodiment of the present invention comprises the sealing resin layer 30, the electronic components 20 embedded in the sealing resin layer 30, and the metal wiring layer formed on the sealing resin layer 30 and bonded to the electrodes 25 of the electronic components 20. The metal wiring layer is composed of the tapered metal plating layer directly bonded to the electrodes 25 of the electronic components 20, and the metal foil 40 integrated with the metal plating layer. The tapered metal plating layer has a two-layered structure of the tapered dry plating layer 50, and the tapered wet plating layer 60, and extends to locally through the internal region of the metal foil 40. Specifically, the tapered dry plating layer 50 has a bended form to be in a direct contact with the electrode 25 of the electronic component 20 and the exposed sealing resin layer 30. The tapered wet plating layer 60 fills the recessed portion of the tapered dry plating layer 50 formed due to the bended form such that the tapered wet plating layer 60 has a form of thickness on the metal foil 40. The width of the tapered metal plating layer in direct contact with the electrode 25 of the electronic component 20 is narrower than that of the tapered metal plating layer in direct contact with the exposed sealing resin layer 30. Together with this, the height of the tapered metal plating layer in direct contact with the electrode 25 of the electronic component 20 is higher than that of the tapered metal plating layer in direct contact with the exposed sealing resin layer 30. This arrangement can suppress the defective connection between the tapered metal plating layer in direct contact with the electrode 25 of the electronic component 20 and the electrode 25 of the electronic component 20.

On the other hand, the width of the tapered metal plating layer in direct contact with the exposed sealing resin layer 30 is wider than that of the tapered metal plating layer in direct contact with the electrode 25 of the electronic component 20. Thus, the part of the tapered metal plating layer in direct contact with the exposed sealing resin layer 30 can serve as the land for soldering the electronic component package 100 to the substrate. Thus, a defective mounting which occur in mounting a solder ball, or a solder flash which occur in reflowing a solder ball can be suppressed.

The present invention may take the following embodiment.

Even when a light-emitting element is used as the electronic component 20 which is a component of the electronic component package of the present invention, a light-emitting element package product can be appropriately manufactured. In this case, a fluorescent layer and a transparent resin layer are preferably used instead of the sealing resin layer 30. Specifically, the fluorescent layer is provided on the light-emitting element disposed on the adhesive carrier 10, and then the transparent resin layer is formed such that the light-emitting element and the fluorescent layer are covered with the transparent resin layer. Thus, the desired light-emitting element package can be obtained.

The material and thickness for the fluorescent layer and the transparent resin layer may be the same as those conventionally used in the general LED packages. The term “light-emitting element” as used herein substantially means an element for emitting light, for example, a light emitting diode (LED), and an electronic component including the light emitting diode. Thus, the term “light-emitting element” as used herein means not only a “bare chip type LED (i.e., LED chip)” but also a “discrete type light-emitting element wherein a molding of the LED chip is provided”. The LED chip may also be a semiconductor laser chip.

In a case where of the package including the light-emitting element as the electronic component, the metal foil 40 can be suitably used as a reflective layer. In this case, the reflective layer is located beneath the light-emitting element. The downward light emitted from the light-emitting element can be effectively reflected by the metal foil 40. As a result, the downward light emitted from the light-emitting element can be eventually reoriented upwardly by the metal foil 40. When the high reflectivity is an important consideration, the metal foil 40 preferably comprises metal material selected from the group of Ag (silver) and Al (aluminum).

It should be noted that the present invention as described above includes the following aspects:

The first aspect: A method for manufacturing an electronic component package, the method comprising the steps:

(i) forming a package precursor in which an electronic component is embedded in a sealing resin layer such that an electrode of the electronic component is exposed at a surface of the sealing resin layer;

(ii) disposing a metal foil having a through-hole on the surface of the sealing resin layer such that the through-hole of the metal foil is positioned in an opposed relation to the electrode of the electronic component; and

(iii) forming a metal plating layer on the metal foil,

wherein the formation of the metal plating layer in the step (iii) is performed by a dry plating process and a subsequent wet plating process, whereby the through-hole of the metal foil is filled with the metal plating layer, and the metal foil and the metal plating layer are integrated with each other.

The Second Aspect: The method according to the first aspect, wherein the dry plating process is performed to form a dry plating layer in direct contact with the electrode of the electronic component via the through-hole, and

the wet plating process is performed to form a wet plating layer in direct contact with the dry plating layer.

The Third Aspect: The method according to the first or second aspect, wherein the dry plating process is performed to form the dry plating layer having a bended form along an outline of the through-hole.

the dry plating is performed to form the dry plating layer having a shape bent along an outline of the through-hole.

The Fourth Aspect: The method according to any one of the first to third aspects, wherein the wet plating process is performed to form the wet plating layer having a form of thickness on the metal foil, completely filling the through-hole.

The Fifth Aspect: The method according to any one of the first to fourth aspects, the through-hole of the metal foil has a tapered shape.

The Sixth Aspect: The method according to any one of the first to fifth aspects, wherein the metal foil has a thickness of 18 μm to 1000 μm.

The Seventh Aspect: The method according to any one of the first to sixth aspects, wherein the metal foil having a further through-hole is disposed in the step (ii), the further hole being positioned in an opposed relation to the surface of the sealing resin layer, and

wherein an opening size of the through-hole positioned in the opposed relation to the electrode is different from that of the further through-hole positioned in the opposed relation to the surface of the sealing resin layer.

The Eighth Aspect: The method according to the seventh embodiment, wherein a plating growth height of the metal plating layer varies with the difference of the opening size.

The Ninth Aspect: The method according to the seventh or eighth aspect, wherein the opening size of the through-hole positioned in the opposed relation to the electrode is smaller than that of the through-hole positioned in the opposed relation to the surface of the sealing resin layer.

The Tenth Aspect: The method according to any one of the first to ninth aspects, wherein the dry plating layer with its thickness of 100 nm to 1000 nm is formed by the dry plating process, whereas the wet plating layer with its thickness (thickness of the layer area on the metal foil, the layer area being not located at the through-hole) of 1 μm to 10 μm is formed by the wet plating process.

The Eleventh Aspect: The method according to any one of the first to tenth aspects, wherein a sputtering is performed as the dry plating process, whereas an electroplating is performed as the wet plating process.

The Twelfth Aspect: The method according to any one of the first to eleventh aspects, wherein the integrated metal foil and metal plating layer are subjected to a patterning treatment to form a metal wiring layer therefrom.

The Thirteenth Aspect: The method according to any one of the first to twelfth aspects, wherein the step (i) of the formation of the package precursor comprises the steps:

(a) placing the electronic component on an adhesive carrier such that the electronic component is attached to the adhesive carrier;

(b) forming a sealing resin layer on the adhesive carrier such that the electronic component is covered with the sealing resin layer; and

(c) peeling away the adhesive carrier from the sealing resin layer, whereby the electrode of the electronic component is exposed at the surface of the sealing resin layer.

The Fourteenth Aspect: The method according to any one of the first to thirteenth aspects, wherein the metal foil comprises an adhesive layer, and the metal foil is disposed such that the adhesive layer makes contact with a surface of the sealing resin layer, the electrode of the electronic component being exposed at the surface of the sealing resin layer.

The Fifteenth Aspect: The method for manufacturing an electronic component package according to any one of the first to fourteenth aspects, wherein a light-emitting element is included as the electronic component, and

instead of forming the sealing resin layer, a fluorescent layer is disposed on the light-emitting element, and thereafter a transparent resin layer is formed to cover the light-emitting element and the fluorescent layer.

The Sixteenth Aspect: An electronic component package, comprising:

a sealing resin layer;

an electronic component embedded in the sealing resin layer; and

a metal wiring layer formed on the sealing resin layer and in contact with an electrode of the electronic component,

wherein the metal wiring layer is composed of a metal plating layer and a metal foil, the metal plating layer being in a direct contact with the electrode of the electronic component and the metal foil being integrated with the metal plating layer,

the metal plating layer has a two-layered structure of a dry plating layer and a wet plating layer, and the dry plating layer has a bended form to be in a direct contact with the electrode of the electronic component, and the wet plating layer fills a recessed portion of the dry plating layer such that the wet plating layer has a form of thickness on the metal foil, the recessed portion being due to the bended form.

The Seventeenth Aspect: The electronic component package according to the sixteenth aspect, wherein the metal plating layer extends locally through an internal region of the metal foil.

The Eighteenth Aspect: The electronic component package according to the sixteenth aspect or seventeenth aspect, wherein the metal plating layer extends to be in direct contact with not only the electrode of the electronic component but also the sealing resin layer.

The Nineteenth Aspect: The electronic component package according to the eighteenth aspect, wherein a solder is provided on the metal plating layer which is in direct contact with the sealing resin layer.

The Twentieth Aspect: The electronic component package according to any one of the sixteenth to nineteenth aspects, wherein a height of the metal plating layer in direct contact with the electrode of the electronic component differs from that of the metal plating layer which is in direct contact with the sealing resin layer.

The Twenty-first Aspect: The electronic component package according to the twentieth aspect, wherein the height of the metal plating layer in direct contact with the electrode of the electronic component is higher than that of the metal plating layer in direct contact with the sealing resin layer.

The Twenty-second Aspect: The electronic component package according to any one of the sixteenth to twenty-first aspects, wherein the metal plating layer has a tapered shape.

The Twenty-third Aspect: The electronic component package according to any one of the sixteenth to twenty-second aspects, wherein the metal foil has a thickness of 18 μm to 1000 μm.

The Twenty-fourth Aspect: The electronic component package according to any one of the sixteenth to twenty-third aspects, wherein a thickness of the metal plating layer (thickness of the layer area other than the recessed portion of the dry plating layer) is thinner than that of the metal foil.

The Twenty-fifth Aspect: The electronic component package according to any one of the sixteenth to twenty-fourth aspects, wherein the dry plating layer has a thickness of 100 nm to 1000 nm, whereas the wet plating layer has a thickness of 1 μm to 10 μm (thickness of the layer area other than the recessed portion of the dry plating layer).

The Twenty-sixth Aspect: The electronic component package according to any one of the sixteenth to twenty-fifth aspects, wherein a light-emitting element is provided as the electronic component, and

instead of forming the sealing resin layer, a fluorescent layer is provided on the light-emitting element, and also a transparent resin layer is provided such that the light-emitting element and the fluorescent layer are covered with the transparent resin layer.

The Twenty-seventh Aspect: The electronic component package according to any one of the sixteenth to twenty-sixth aspects, wherein the metal foil comprises an adhesive layer, and the metal foil is disposed such that the adhesive layer makes contact with a surface of the sealing resin layer, the electrode of the electronic component being exposed at the surface of the sealing resin layer.

The Twenty-eighth Aspect: The electronic component package according to any one of the sixteenth to twenty-seventh aspects, further comprising a resist layer provided with respect to the metal wiring layer.

The Twenty-ninth Aspect: The electronic component package according to any one of the sixteenth to twenty-eighth aspects, wherein at least a part of the metal foil and the metal plating layer serve as a heat-releasing part for the electronic component package.

While some embodiments of the present invention have been hereinbefore described, they are merely the typical embodiments. It will be readily appreciated by those skilled in the art that the present invention is not limited to the above embodiments, and that various modifications are possible without departing from the scope of the present invention.

### Examples

An electronic component package of the present invention was fabricated through the following steps.

Materials used to manufacture of the electronic component package of the present invention were as follows:

1. Adhesive carrier (Adhesive film): Single-faced adhesive tape (adhesive layer of about 15 μm and polyester film of about 200 μm in thickness) about 200 mm×about 200 mm

2. Sealing resin layer: Liquid epoxy resin

3. Metal foil: Copper foil (of about 18 μm in thickness) with gloss surface on one face/roughened surface on resin-side face

The electronic component package of the present invention was obtained after the following processes.

| | |
|---|---|
| Lamination | Lamination of copper foil on adhesive film (such that gloss surface of copper foil is in contact with |
| | adhesive film). |
| DFR lamination | Lamination of dry film resist on adhesive film having copper foil (single face lamination). |
| Development | Development of DFR with alkaline developer. |
| Etching | Etching of copper foil with ferric chloride solution. |
| Removal | Swelling removal of DFR with alkaline stripping liquid. |
| Mounting | Mounting of electronic component (especially, placing of electronic component with reference to |
| | patterned portion of copper foil). |
| Sealing resin preparation | Metering of predetermined amount of liquid epoxy rein, and then filling die therewith |
| Vacuum heat press | Charging die in heat press (heated at about 50° C.), and decompression into a pressure of about - |
| | 0.1 MPa by vacuum pump, followed by holding it for about five minutes. Then, heating up to about |
| | 120° C. and pressurizing up to about 0.1 MPa, followed by holding it for about 15 minutes. |
| Demolding | Removal of die from heat press, followed by cooling thereof. Then, sample was taken out from die. |
| Peeling | Peeling of adhesive film to provide precursor |
| Lamination | Align the copper foil having through-holes formed by etching, with the precursor, followed by heating |
| | at about 120° C. and pressuring (at about 0.1 MPa) of the die, and then holding for about 15 |
| | minutes. |
| After-cure | Complete curing by dryer (about 150° C.) for about 60 minutes (in the air). |
| Sputtering (Ti/Cu) | Providing precursor in sputtering apparatus. Then, reverse sputtering plus Ti sputtering (about 200 Å), |
| | and Cu sputtering (about 1000 Å) |
| Electrolytic Cu plating | Electrolytic Cu plating to provide desired thickness (up to about 35 um) of plating layer. |
| Liquid resist formation | Application of liquid resist ink by spin-coater. Drying until no tack is provided. |
| Development | Development of liquid resist with alkaline developer. |
| Etching | Etching of Cu with ferric chloride solution. Then, removal of Ti layer with Ti etching liquid. |
| Removal | Removal of liquid resist with alkaline stripping liquid |
| Soder resist application | Screen printing of photosensitive solder resist print ink. Heat treatment until no adhesiveness is |
| | provided. |
| Development | UV irradiation via pattenred film, followed by development. |
| Curing | Complete cure of SR by heat treatment. |
| Dicing | Cut into pieces with desired size by blade (with its width dimension of about 0.2 mm) of dicer |
| | device. |
| Stamping | Stamping of serial number on surface of sealing resin. |
| Inspectation | Examining of electrical function. |
| Completion | Completion |

Through the above-mentioned processes, the metal foil 40 of the metal wiring layer was in direct contact with the sealing resin layer 30, and the metal plating layer of the metal wiring layer was in direct contact with the electrodes 25 of the electronic components 20, which enabled the effective heat-releasing from the electronic components through the metal foil 40 and the electrodes 25 of the electronic components 20.

Further, the soldering was not performed in the package, which can avoid inconveniences, including solder flash to thereby improve the connection reliability. Moreover, the packaging can be achieved in an easy process without using a substrate, as compared to the wire bonding or flip-chip packaging, thereby reducing the cost of the package.

### INDUSTRIAL APPLICABILITY

The present invention can be suitably used in various applications of electronics packaging field. For example, the present invention can be suitably available in an electric source package (e.g., POL converter such as voltage step down converter), a LED package, a module with a built-in component.

### CROSS REFERENCE TO RELATED PATENT APPLICATION

The present application claims the right of priorities of Japan patent application No. 2012-279830 (filing date: Dec. 21, 2012, title of the invention: ELECTRONIC COMPONENT PACKAGE AND METHOD FOR MANUFACTURING THE SAME), the whole contents of which are incorporated herein by reference.

### EXPLANATION OF REFERENCE NUMERALS

10 Adhesive carrier
11 Adhesive layer
12 Supporting base
20 Electronic component
25 Electrode
30 Sealing resin layer
40 Metal foil
40′ Metal foil with adhesive layer
50 Dry plating layer
60 Wet plating layer
70 Resist layer
80 Metal pattern layer
90 Adhesive layer
100′ Precursor of electronic component package
100 Electronic component package

1. A method for manufacturing an electronic component package, the method comprising the steps:
(i) forming a package precursor in which an electronic component is embedded in a sealing resin layer such that an electrode of the electronic component is exposed at a surface of the sealing resin layer;
(ii) disposing a metal foil having a through-hole on the surface of the sealing resin layer such that the through-hole of the metal foil is positioned in an opposed relation to the electrode of the electronic component; and
(iii) forming a metal plating layer on the metal foil,
wherein the formation of the metal plating layer in the step (iii) is performed by a dry plating process and a subsequent wet plating process, whereby the through-hole of the metal foil is filled with the metal plating layer, and the metal foil and the metal plating layer are integrated with each other.

2. The method according to claim 1, wherein the dry plating process is performed to form a dry plating layer in direct contact with the electrode of the electronic component via the through-hole, and
the wet plating process is performed to form a wet plating layer in direct contact with the dry plating layer.

3. The method according to claim 2, wherein the dry plating process is performed to form the dry plating layer having a bended form along an outline of the through-hole.

4. The method according to claim 2, wherein the wet plating process is performed to form the wet plating layer having a form of thickness on the metal foil, completely filling the through-hole.

5. The method according to claim 1, wherein the through-hole of the metal foil has a tapered shape.

6. The method according to claim 1, wherein the metal foil has a thickness of 18 μm to 1000 μm.

7. The method according to claim 1, wherein the metal foil having a further through-hole is disposed in the step (ii), the further hole being positioned in an opposed relation to the surface of the sealing resin layer, and
wherein an opening size of the through-hole positioned in the opposed relation to the electrode is different from that of the further through-hole positioned in the opposed relation to the surface of the sealing resin layer.

8. The method according to claim 7, wherein a plating growth height of the metal plating layer varies with the difference of the opening size.

9. The method according to claim 7, wherein the opening size of the through-hole positioned in the opposed relation to the electrode is smaller than that of the further through-hole positioned in the opposed relation to the surface of the sealing resin layer.

10. The method according to claim 2, wherein the dry plating layer with its thickness of 100 nm to 1000 nm is formed by the dry plating process, whereas the wet plating layer with its thickness (thickness of the layer area on the metal foil, the layer area being not located at the through-hole) of 1 μm to 10 μm is formed by the wet plating process.

11. The method according to claim 1, wherein a sputtering is performed as the dry plating process, whereas an electroplating is performed as the wet plating process.

12. The method according to claim 1, wherein the integrated metal foil and metal plating layer are subjected to a patterning treatment to form a metal wiring layer.

13. The method according to claim 1, wherein the step (i) of the formation of the package precursor comprises the steps:
(a) placing the electronic component on an adhesive carrier such that the electronic component is attached to the adhesive carrier;
(b) forming a sealing resin layer on the adhesive carrier such that the electronic component is covered with the sealing resin layer; and
(c) peeling away the adhesive carrier from the sealing resin layer, whereby the electrode of the electronic component is exposed at the surface of the sealing resin layer.

14. The method according to claim 1, wherein the metal foil comprises an adhesive layer, and the metal foil is disposed such that the adhesive layer makes contact with a surface of the sealing resin layer, the electrode of the electronic component being exposed at the surface of the sealing resin layer.

15. The method according to claim 1, wherein a light-emitting element is included as the electronic component, and
instead of forming the sealing resin layer, a fluorescent layer is disposed on the light-emitting element, and thereafter a transparent resin layer is formed to cover the light-emitting element and the fluorescent layer.

16. An electronic component package, comprising:
a sealing resin layer;
an electronic component embedded in the sealing resin layer; and
a metal wiring layer formed on the sealing resin layer and in contact with an electrode of the electronic component,
wherein the metal wiring layer is composed of a metal plating layer and a metal foil, the metal plating layer being in a direct contact with the electrode of the electronic component and the metal foil being integrated with the metal plating layer,
the metal plating layer has a two-layered structure of a dry plating layer and a wet plating layer, and the dry plating layer has a bended form to be in a direct contact with the electrode of the electronic component, and the wet plating layer fills a recessed portion of the dry plating layer such that the wet plating layer has a form of thickness on the metal foil, the recessed portion being due to the bended form.

17. The electronic component package according to claim 16, wherein the metal plating layer extends locally through an internal region of the metal foil.

18. The electronic component package according to claim 16, wherein the metal plating layer extends to be in direct contact with not only the electrode of the electronic component but also the sealing resin layer.

19. The electronic component package according to claim 18, wherein a solder is provided on the metal plating layer in direct contact with the sealing resin layer.

20. The electronic component package according to claim 16, wherein a height of the metal plating layer in direct contact with the electrode of the electronic component differs from that of the metal plating layer in direct contact with the sealing resin layer.

21. The electronic component package according to claim 20, wherein the height of the metal plating layer in direct contact with the electrode of the electronic component is higher than that of the metal plating layer in direct contact with the sealing resin layer.

22. The electronic component package according to claim 16, wherein the metal plating layer has a tapered shape.

23. The electronic component package according to claim 16, wherein the metal foil has a thickness of 18 μm to 1000 μm.

24. The electronic component package according to claim 16, wherein a thickness of the metal plating layer (thickness of the layer area other than the recessed portion of the dry plating layer) is thinner than that of the metal foil.

25. The electronic component package according to claim 16, wherein the dry plating layer has a thickness of 100 nm to 1000 nm, whereas the wet plating layer has a thickness of 1 μm to 10 μm (thickness of the layer area other than the recessed portion of the dry plating layer).

26. The electronic component package according to claim 16, wherein a light-emitting element is provided as the electronic component, and
instead of forming the sealing resin layer, a fluorescent layer is provided on the light-emitting element, and also a transparent resin layer is provided such that the light-emitting element and the fluorescent layer are covered with the transparent resin layer.

27. The electronic component package according to claim 16, wherein the metal foil comprises an adhesive layer, and the metal foil is disposed such that the adhesive layer makes contact with a surface of the sealing resin layer, the electrode of the electronic component being exposed at the surface of the sealing resin layer.

28. The electronic component package according to claim 16, further comprising a resist layer provided with respect to the metal wiring layer.

29. The electronic component package according to claim 16, wherein at least a part of the metal foil and the metal plating layer serve as a heat-releasing part for the electronic component package.
